(19) United States
(12) Patent Application Publication
(10) Pub. No.: US 2024/0178819 A1
(43) Pub. Date: May 30, 2024

(54) LINEAR DECIMATION FILTERS FOR INCREMENTAL DELTA-SIGMA ANALOG TO DIGITAL CONVERTERS

(71) Applicant: Qatar Foundation for Education, Science and Community Development, Doha (QA)

(72) Inventors: Bo Wang, Doha (QA); Jens Schneider, Doha (QA)

(21) Appl. No.: 18/509,481

(22) Filed: Nov. 15, 2023

Related U.S. Application Data
(60) Provisional application No. 63/426,232, filed on Nov. 17, 2022.

(51) Int. Cl. H03H 17/02; H03K 19/20

(52) U.S. Cl. CPC H03H 17/02; H03K 19/20

(57) ABSTRACT

Linear decimation filters for incremental delta-sigma analog to digital converters are provided with a data rate signal input; a digital signal input; a weight generator connected to the signal input to generate a weight signal via a weight signal output; an adder having a digital signal output, a first addition input connected to the weight signal output, and a second addition input connected to the digital signal output; and an AND-gate having a first input connected to the input data rate signal input and a second input connected to the digital signal input to produce a logical output that gates output from the digital signal output of the adder.

### CROSS-REFERENCES TO RELATED APPLICATIONS

The present disclosure claims the benefit of U.S. Provisional Patent Application No. 63/426,232 entitled “LINEAR DECIMATION FILTERS FOR INCREMENTAL DELTA-SIGMA ANALOG TO DIGITAL CONVERTERS” and filed on Nov. 17, 2022, which is incorporated herein by reference in its entirety.

### TECHNICAL FIELD

The present disclosure relates to a linear decimation filter for use with incremental Delta-Sigma Analog to Digital Converters (ADCs).

### BACKGROUND

Incremental data converters (IDCs), also called incremental delta-sigma (ΔΣ) analog-to-digital converters (ADC), are popular for Direct Current (DC) and low-bandwidth signal conversion due to the unique property thereof of achieving high-resolutions, without requiring precise device matching and being free from idle tones. Most research hitherto investigated optimizing the modulator design, employing multi-step conversion for more aggressive quantization noise shaping, or using a VCO-based quantizer to improve energy efficiency.

SUMMARY

For incremental delta-sigma data converters (IDCs), it becomes more challenging to squeeze any energy reduction from the modulators, while the use of more efficient decimation filters could make a big difference. The present disclosure presents the derivation and analysis of two linear decimation filters, namely, L₂min² and its symmetric version L₂min^{2s}. Owing to the low thermal noise penalty (e.g., 1.2) and strong quantization noise suppression, the described filters can outperform the traditionally used CoI¹, CoI², CoI³, sinc², or sinc³ filters and are excellent candidates for first-and second-order IDC output decimation. Digital implementation of the provided filters is also quite hardware-friendly. Methods presented herein can also be used to derive efficient linear filters for other higher-order modulators.

In various aspects, linear decimation filters for incremental delta-sigma analog to digital converters are provided with a data rate signal input (e.g., a clock); a digital signal input: a weight generator to generate a weight signal via a weight signal output updated at the pace of the date rate signal input: an adder having a digital signal output, a first addition input connected to the weight signal output, and a second addition input connected to the digital signal output: and an AND-gate having a first input connected to the input data rate signal input and a second input connected to the digital signal input to produce a logical output that gates output from the digital signal output of the adder.

Additional features and advantages of the disclosed method and apparatus are described in, and will be apparent from, the following Detailed Description and the Figures. The features and advantages described herein are not all-inclusive and, in particular, many additional features and advantages will be apparent to one of ordinary skill in the art in view of the figures and description. Moreover, it should be noted that the language used in the specification has been principally selected for readability and instructional purposes, and not to limit the scope of the inventive subject matter.

### BRIEF DESCRIPTION OF THE DRAWINGS

FIG. 1 illustrates an example design for an L₂min² filter for 1-bit input, according to aspects of the present disclosure.

FIG. 2 illustrates an example design for an L₂min² filter for 1-bit input, according to aspects of the present disclosure.

FIG. 3 is a flowchart of an example method of designing an IDC using the proposed filters, according to aspects of the present disclosure.

### DETAILED DESCRIPTION

The present disclosure discusses deriving an efficient linear decimation filter L₂min² for a first-order IDC in a systematic way, with the aim of achieving high accuracy by optimizing an L₂-optimal function. For periodic noise suppression, a symmetric filter, L₂min^{2s}, is provided. With the capability of providing more frequency notches, L₂min^{2s} can suppress periodic noise without greatly sacrificing the IDC's sampling rate as compared to the high-order sinc filters. Overall, with a low thermal noise penalty (e.g., 1.2) and strong quantization noise suppression capability, the proposed filters can outperform the traditionally used CoI¹, CoI², CoI³, sinc², or sinc³ filters when applied for first- and second-order IDC output decimation.

For clarity, if not specified otherwise, all analog voltage signals discussed herein are normalized to the IDC's reference V_{ref}, while all signal and noise powers are normalized to V²_{ref}.

The discrete outputs (n, Sₙ₊₁) of the IDC effectively track the input ramp (n, nvin) during modulation. If (n, Sₙ₊₁) are known (e.g., reproduced using the modulator output), the input Vin can be estimated by minimizing the Mean Square Error (MSE) between the tracking envelope and the input ramp. Accordingly, linear least squares regression can be used to minimize or reduce the cost function in Formula 1 with respect to Vᵢₙ.

$$\\ \begin{matrix}ξ = \frac{1}{2} {\sum }_{n = 1}^{N} {( {s}_{n + 1} - n \cdot {v}_{in} )}^{2} & Formula 1\end{matrix}$$

Because ζ is a convex quadratic, the location of vanishing gradient is the location of ζ's only minimum, and by substituting sn+1 and [0]=0, formula 2 yields an input estimation \hat{V}ᵢₙ.

$$\\ \begin{matrix}{\hat{v}}_{in} = {\sum }_{n = 1}^{N} ( n \cdot {s}_{n + 1} ) / {\sum }_{n = 1}^{N} {{n}^{}}^{2} = {\sum }_{n = 1}^{N} ( n {\sum }_{i = 1}^{n} q [ i ] ) / {\sum }_{n = 1}^{N} {{n}^{}}^{2} & Formula 2\end{matrix}$$

Regrouping the numerator yields co-factors for each bit, which can be simplified according to Formula 3 to result in the weighting function or kernel of the decimation filter.

$$\\ \begin{matrix}{\hat{v}}_{in} = {\sum }_{n = 1}^{N} ( q [ n ] {\sum }_{i = n}^{N} i ) / {\sum }_{n = 1}^{N} {{n}^{}}^{2} & Formula 3\end{matrix}$$

The n^{th} coefficient wₙ of the filter before normalization can be expressed as shown in Formula 4.

$$\\ \begin{matrix}{w}_{n} = {\sum }_{i = 1}^{N} i - {\sum }_{i = 1}^{n - 1} i = \frac{{{N}^{}}^{2} + N}{2} - \frac{{{n}^{}}^{2} - n}{2} & Formula 4\end{matrix}$$

The filter kernel is derived based on the least MSE method and has concavely smooth-decaying weights, and differs significantly from the often recommended moving average filter with uniform weights. As used herein, the filter is referred to as an L₂min² because it is derived with L₂-norm, and its weight has a second-order dependency on the bit index.

Although higher-order IDCs can be analyzed in the same fashion to obtain L₂-optimal filters, the weighting functions will have a higher-order dependency on the bit index and the digital implementation could be costly.

When applying the L₂min² filter to a first order 1-bit IDC, the present disclosure assumes finite operation like a typical ΔΣ modulator that has an output that satisfies Formula 5, where (z) is the quantization error of the 1-bit quantizer.

q( [symbol] )= [symbol] ⁻¹Vᵢₙ+(1− [symbol] ⁻¹)ε( [symbol] ) Formula 5

By applying the derived L₂min² filter weights, the decimated digital output is provided according to Formula 6 and Formula 7, which contain the input and a linear sum of the quantization errors.

$$\\ \begin{matrix}{D}_{out} = \frac{1}{{\sum }_{n = 1}^{N} {w}_{n}} {\sum }_{n = 1}^{N} ( {w}_{n} \cdot q [ n ] ) & Formula 6\end{matrix}$$

$$\\ \begin{matrix}{D}_{out} = {v}_{in} + \frac{6}{N ( N + 1 ) ( 2 N + 1 )} {\sum }_{n = 1}^{N} n ε [ n ] & Formula 7\end{matrix}$$

If [n] is independent, zero mean, and uniformly distributed between ±1 during one conversion, its variance is σ=4/12. Accordingly, the standard deviation of the quantization error in Dₒᵤₜ can be calculated according to Formula 8.

$$\\ \begin{matrix}{σ}_{q} = \sqrt{\frac{6}{N ( N + 1 ) ( 2 N + 1 )}} \cdot {σ}_{ε} \approx \sqrt{\frac{3}{{{N}^{}}^{3}}} {σ}_{ε} & Formula 8\end{matrix}$$

To achieve nbit-bit resolution (considering only quantization noise) within the input range ±Umax, the required conversion cycles N using the L₂min² decimation filter can be derived with the 3-sigma rule according to Formula 9.

3σ_{q}=LSB/2=1/2·2Uₘₐₓ/2ⁿ^{_{bit}}. Formula 9

This is much less than the conversion cycles needed by a digital counter for decimation (i.e., 2^{m}^{^{bit}}/Umax), and indicates the superior quantization noise suppression capability of L₂min². Although the MSE of the converter is minimized by using L₂min² for decimation, due to the inherent non-uniform code length of the first-order modulator, it has several “dead zone” regions with large quantization error spikes constraining the absolute precision of the converter. Even an ideal decoder cannot mitigate these error spikes: however, injecting a random dither signal (e.g., Gaussian dither, uniform dither, etc.) before the quantizer can suppress peak error. Dithering can also bring e[n] closer to a uniform distribution for DC or slowly time-varying inputs, thereby keeping the previously-made assumptions valid.

If a uniform dither signal U{−1/3, 1/3} were applied to the quantizer, sigma 2e would increase to (4+2/3)/12. Based on statistical simulations, the input range reduces to Uₘₐₓ≈2/3 to avoid overloading the quantizer, and Formula 9 may be modified as shown in Formula 10 to achieve nbit-bit resolution within ±Uₘₐₓ.

N_{with_dither}=2.2·(2ⁿ^{_{bit}}/Uₘₐₓ)^{2/3} Formula 10

The output of Formula 10 agrees well with the numerical results shown in simulation, and the “dead zones” are successfully mitigated.

Different from most algorithmic decoders applicable only for constant inputs, the L₂min² filter can be applied for IDCs with varying inputs (dithering is not required for fast-changing inputs).

In practical ΔΣ modulator implementations, an unbiased thermal noise component would effectively add to the input (e.g., thermal noise, a Gaussian noise with variance σ_{g2}). It is known that a moving averaging filter (with uniform filter weights) can suppress the random noise to a level of σ_{g2}/N by decimating N samples. For any other filters with non-uniform weights, this level of noise averaging cannot be achieved. The term thermal noise penalty factor βₜ (the smaller the better) is often used to represent the increased noise compared to that of using a simple moving average filter (whose βₜ is 1). For a linear filter with the weight being {wₙ, n∈Z+, 1≤n≤N}, its βₜ is calculated according to Formula 11, and for the L₂min² filter according to Formula 12.

$$\\ \begin{matrix}{β}_{t} = \frac{{\sum }_{n = 1}^{N} {w}_{n}^{{}_{} 2}}{{( {\sum }_{n = 1}^{N} {w}_{n} )}^{2}} / \frac{1}{N} = N \frac{{\sum }_{n = 1}^{N} {w}_{n}^{{}_{} 2}}{{( {\sum }_{n = 1}^{N} {w}_{n} )}^{2}} & Formula 11\end{matrix}$$

$$\\ \begin{matrix}{β}_{t} = {N [ \frac{6}{N ( N + 1 ) ( 2 N + 1 )} ]}^{2} {\sum }_{n = 1}^{N} {[ \frac{{{N}^{}}^{2} + N - {{n}^{}}^{2} + n}{2} ]}^{2} = \frac{6}{5} ( 1 - \frac{N}{2 {{N}^{}}^{2} + 3 N + 1} ) < \frac{6}{5} . & Formula 12\end{matrix}$$

Accordingly, the output variance caused by thermal noise can be calculated according to Formula 13, which indicates a reasonably good and also smaller noise penalty than that of CoI² and CoI³. Besides its good quantization noise suppression capability, the lower output variance due to thermal noise is another advantage of the L₂min² filter when applied to thermal-noise-limited converters.

σₒᵤₜ²<6/5·σ_{g}²/N Formula 13

The derived L₂min² filter with a decimation ratio N has the finite-impulse response (FIR) transfer function shown in Formula 14.

$$\\ \begin{matrix}H ( 𝓏 ) = \frac{1}{{\sum }_{n = 1}^{N} {w}_{n}} {\sum }_{i = 1}^{N} {w}_{i} {{𝓏}^{}}^{i - N} = \frac{6}{N ( N + 1 ) ( 2 N + 1 )} {\sum }_{i = 1}^{N} \frac{{{N}^{}}^{2} + N - {{i}^{}}^{2} + i}{2} {{𝓏}^{}}^{i - N} & Formula 14\end{matrix}$$

Although the closed-form expression can be calculated analytically, this has little practical importance. Instead, its frequency response can be found by taking the DFT of its impulse response (padding with extra zeros). Similar to CoI², L₂min² does not provide any frequency notches in the transfer characteristic due to its asymmetric impulse response. Only the 1/f term dominates, and it exhibits a mild 20 dB/decade out-of-band attenuation with a passband droop of about 2.7 dB.

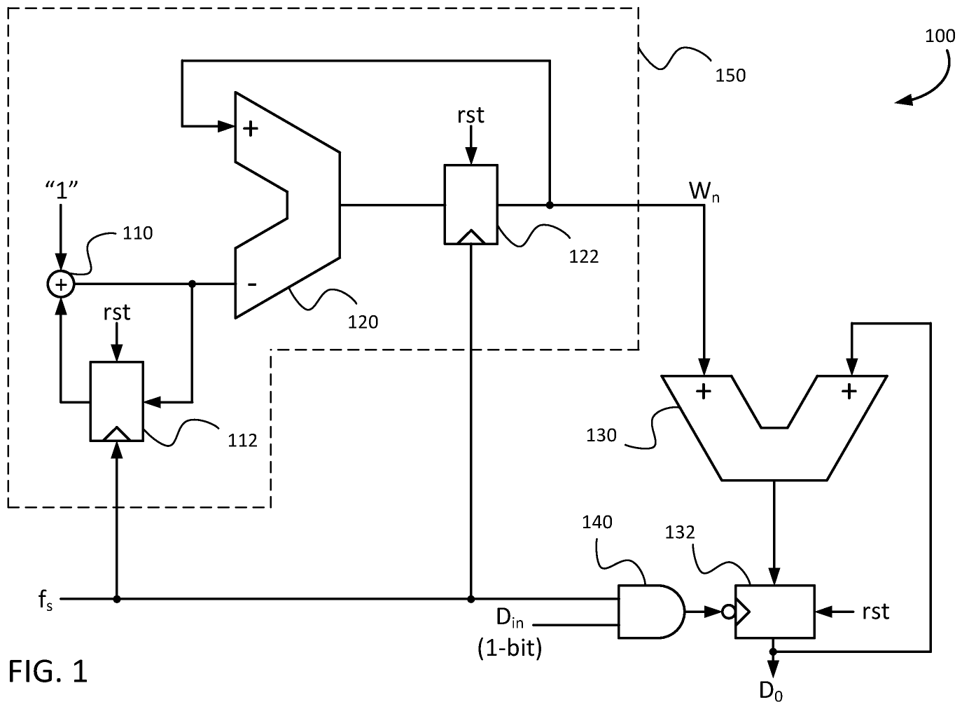

FIG. 1 illustrates an example design for an L₂min² filter 100 for 1-bit input, according to aspects of the present disclosure. The design uses a ripple counter 110, a subtractor 120, an adder 130, and an AND-gate 140. Initially, a register 112 of the ripple counter 110 is reset to “0”, while the subtractor 120 is reset to w_{N}=N(N+1)/2. The weight generator then updates its output wₙ at fₛ (the input data rate). The adder 130 is gated by Dᵢₙ and is updated only when the input bit is “1”. The adder 130 operates at the falling edge of fₛ, thus the correct weight wₙ is prepared.

The design uses the worst-case register growth to calculate the bit-width of each building block. The required register width for the register 112 of the ripple counter 110 is [log₂ N+1)], the register 122 of the subtractor 120 is [log₂(N2+N)−1], and the register 132 of the adder 130 is (3[log₂(N)]−1). Truncation can be applied to the subtractor 120 to reduce the number of registers. For example, a 12.6-bit resolution can be achieved with an N of 1024 using L₂min² for output decimation. Through experimental testing, the bit-widths for the ripple counter 110, subtractor 120, and adder 130 are 11, 20, and 29, respectively, which have proven to provide superior performance with reduced overhead. In the present example, the resolution loss is only 0.06-bit after truncating the subtractor 120 (and thus the adder 130) bit-width by 4-bit. Based on numerical simulation results, truncating the subtractor bit-width by ˜20% of the theoretical value thereof has negligible influence on the converter performance.

Collectively, the ripple counter 110, counter register 112, subtractor 120, and subtractor register 122 may be referred to as a weight generator 150.

For multi-bit (i.e., Bᵢₙ bit) input of [n], an Bᵢₙ×[log₂(N2+N)−1] bit multiplier is used to compute q[n]·wₙ, which would significantly increase the hardware overhead.

To suppress period noise (e.g., line frequency disturbances), the present disclosure provides an improved filter L₂min^{2s} with symmetric impulse response based on the L₂min² kernel. To construct such a new impulse response with (2N−1) points (e.g., odd number, and the IDC's OSR is now 2N−1 instead of N), wₙ is firstly left-shifted by 1-point, mirrored around the y-axis, and then right-shifted by N-points, with the analytical form of the symmetric filter expressed as shown in Formula 15, with wn=0 for n≤0 or n≥2N.

$$\\ \begin{matrix}{w}_{n} = \{ \begin{matrix}\frac{{{N}^{}}^{2} + N}{2} - \frac{{( N - n + 1 )}^{2} - ( N - n + 1 )}{2} \\ n = 1 , 2 , … , N ; \\ \frac{{{N}^{}}^{2} + N}{2} - \frac{{( n - N + 1 )}^{2} - ( n - N + 1 )}{2} \\ n = N + 1 , … , 2 N - 1 ;\end{matrix} & Formula 15\end{matrix}$$

The normalized weighing function of L₂min^{2s} plots the first-order (same as CoI¹), second-order, and third-order moving average filters with symmetric weights and periodic noise suppression capabilities. These moving average filters are also called sinc^{L}-filter, with L representing its order.

The L₂min^{2s} filter has the same thermal noise penalty factor as the L₂min² filter, 6/5. L₂min^{2s} again shows its advantage (e.g., 0.13, 0.47 smaller than that of sinc², sinc³, respectively) if applied to thermal-noise-limited converters.

For different filters, if the first notches thereof are all placed at the same frequency (e.g., 50 Hz or 60 Hz), the conversion speed of a high-order sinc filter is slower. In other words, to create the same number of frequency notches between 0 to fₛ, high-order sinc filters require a proportionally longer input bitstream length. The tradeoff between frequency notch location, stopband attenuation, and conversion speed is a major drawback for sinc filters. However, for a (2N−1) point symmetric L₂min^{2s} filter, its z-domain transfer function is expressed according to Formula 16, which creates (2N−2) frequency notches between 0 to fₛ, which is 2 and 3 times that of sinc² and sinc³ filters with the same filter length, respectively.

$$\\ \begin{matrix}H ( 𝓏 ) = \frac{1}{{\sum }_{n = 1}^{2 N - 1} {w}_{n}} {\sum }_{i = 1}^{2 N - 1} {w}_{i} \cdot {{𝓏}^{}}^{i - ( 2 N - 1 )} & Formula 16\end{matrix}$$

Accordingly, the frequency of the first notch for the L₂min^{2s} filter is at ˜3/(4N)·fₛ.

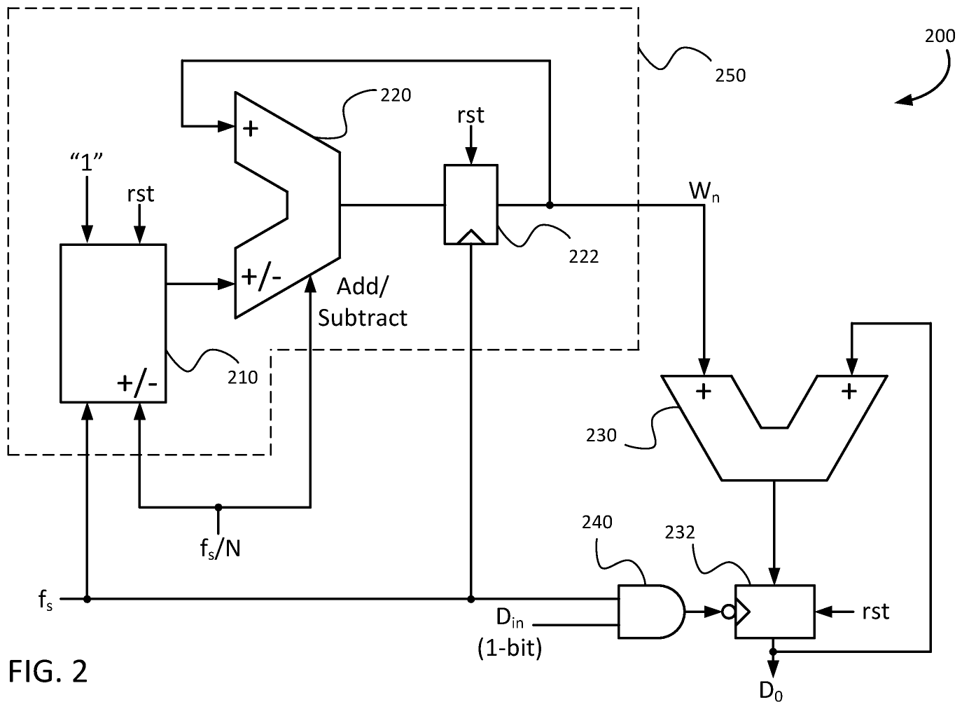

FIG. 2 illustrates an example design for an L₂min² filter 200 for 1-bit input, according to aspects of the present disclosure. Initially, the counter output is reset to N, and the counter 210 is configured as a down-counter. A subtractor/adder 220 performs as an adder with an initial output reset to 0. After operating for N clock cycles, the output of the counter 210 becomes 0, and the counter 210 is then reconfigured as an up-counter while the subtractor/adder 220 is reconfigured as a subtractor. The decimator 200 then operates for another (N−1) clock cycles. Finally, the filter is reset for the next conversion. For 1-bit input, the required bit-width for the counter 210, subtractor/adder 220, and adder 230 is [log₂(N+1)], [log₂(N₂+N)−1], and 3[log₂(N)], respectively. Similarly, bit truncation of the subtractor/adder block, and adder 230 is [log₂(N+1)], [log₂(N₂+N)−1], and 3[log₂(N)], respectively. Similarly, bit truncation of the subtractor/adder 220 can be applied. The conclusion drawn earlier still holds that truncating the subtractor/adder 220 bit-width (and thus the adder bit-width) by ˜0.2·[log₂(N₂+N)−1] does not affect the converter performance.

Collectively, the counter 210, counter register, adder/subtractor 220, and adder/subtractor register 222 may be referred to as a weight generator 250.

Using different decimation filters can significantly affect the performance of an IDC. This present disclosure presents two linear filters (e.g., L₂min² and the symmetric version thereof: L₂min^{2s}) applicable for first- and second-order modulator output decimation. Particularly, besides its low thermal noise penalty and strong stopband attenuation, L₂min^{2s} provides (2N−2) frequency notches with a filter kernel length of 2N−1 point. This is a significant advantage for periodic noise suppression, especially considering that it does not greatly sacrifice the IDC output data rate compared to high-order sinc filters.

Overall, owing to the low thermal noise penalty and high quantization noise suppression capabilities, L₂min² and L₂min^{2s} decimation filters are excellent options for first-order and second-order IDC output decimation where CoI¹, CoI², CoI³, sinc², or sinc³ filters are traditionally employed. Theoretically, the proposed filters can also be used in non-incremental ΔΣ data converters.

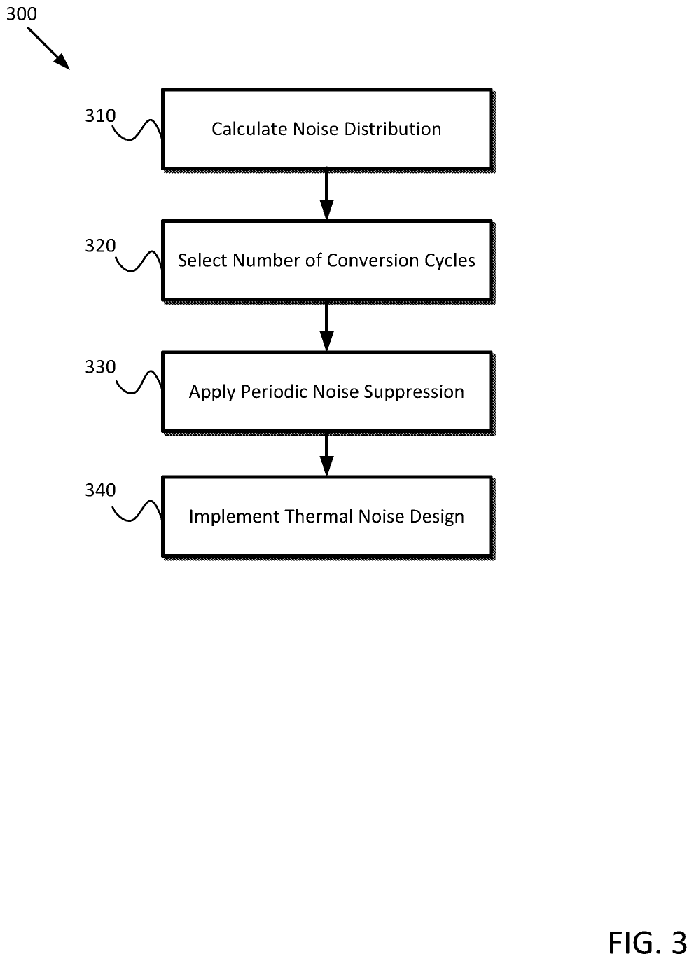

FIG. 3 is a flowchart of an example method 300 of designing an IDC using the proposed filters, according to aspects of the present disclosure. An example design process with an aim of achieving 17-bit peak-to-peak thermal-noise-limited resolution for an input range of ±0.6 V, a 1.2 V reference voltage, a sampling clock frequency fs of 40 kHz, and a periodic frequency noise at 50 Hz (i.e., 1/800·fs) is provided with the operations of method 300 to illustrate the design process, but other design goals may be used with the method 300 described herein, which may yield different final designs for the IDC, without departing from the spirit of the present disclosure.

At block 310, noise distribution is calculated. Achieving 17-bit within ±0.6 V means one LSB is 2·0.6/217=9.2 μV. For peak-to-peak resolution, by applying a 3-sigma rule, the allowable total noise standard deviation is σₙ=9.2 μV/2/3=1.6 μV. Thus, the total noise power in the decimated output is σₙ₂=2.56 pV². If quantization noise contributes 20% of the total noise while 80% is from thermal noise, the allowed quantization noise power is σ_{q2}=0.5 pV². This is equivalent to achieving 18.1-bit quantization-noise-only resolution within ±0.6 V (Umax is 0.6/1.2=0.5).

At block 320, the number of conversion cycles is selected. A multi-bit second-order modulator is preferred for such a high-resolution IDC. Considering the requirement of periodic noise suppression, some embodiments use an L₂min² or an L₂min^{2s} linear decimation filter for decimation. For this example, the number of conversions cycle chosen may be l=9 considering the DAC implementation and matching complexity.

At block 330, periodic noise suppression is applied. To suppress the periodic noise, some embodiments place the first notch 3/(4N)·fₛ at 50 Hz. Then, N should be 600, and the total number of conversion cycles is 1200, which is high enough for quantization noise suppression as calculated per block 310.

At block 340, thermal noise design is implemented. After knowing the thermal noise budget (0.8·2.56 pV²), the total conversion cycles, and considering the filter's thermal noise penalty (i.e., 1.2), the IDC's input-referred thermal noise budget is about 2.06 pV²·1145/1.2≈2 nV². The modulator schematic can then be designed after a system-level verification.

As used herein, various units of measure may be referred to by associated short forms as set by the International System of Units (SI), which one of ordinary skill in the relevant art will be familiar with.

As used herein, “about,” “approximately” and “substantially” are understood to refer to numbers in a range of the referenced number, for example the range of −10% to +10% of the referenced number, preferably −5% to +5% of the referenced number, more preferably -1% to +1% of the referenced number, most preferably −0.1% to +0.1% of the referenced number.

Furthermore, all numerical ranges herein should be understood to include all integers, whole numbers, or fractions, within the range. Moreover, these numerical ranges should be construed as providing support for a claim directed to any number or subset of numbers in that range. For example, a disclosure of from 1 to 10 should be construed as supporting a range of from 1 to 8, from 3 to 7, from 1 to 9, from 3.6 to 4.6, from 3.5 to 9.9, and so forth.

As used in the present disclosure, a phrase referring to “at least one of” a list of items refers to any set of those items, including sets with a single member, and every potential combination thereof. For example, when referencing “at least one of A, B, or C” or “at least one of A, B, and C”, the phrase is intended to cover the sets of: A, B, C, A-B, B-C, and A-B-C, where the sets may include one or multiple instances of a given member (e.g., A-A, A-A-A, A-A-B, A-A-B-B-C-C-C, etc.) and any ordering thereof. For avoidance of doubt, the phrase “at least one of A, B, and C” shall not be interpreted to mean “at least one of A, at least one of B, and at least one of C”.

Although the present invention has been described in certain specific aspects, many additional modifications and variations would be apparent to those skilled in the art. In particular, any of the various processes described above can be performed in alternative sequences and/or in parallel (on the same or on different computing devices) in order to achieve similar results in a manner that is more appropriate to the requirements of a specific application. It is therefore to be understood that the present invention can be practiced otherwise than specifically described without departing from the scope and spirit of the present invention. Thus, embodiments of the present invention should be considered in all respects as illustrative and not restrictive. It will be evident to the annotator skilled in the art to freely combine several or all of the embodiments discussed here as deemed suitable for a specific application of the invention. Throughout this disclosure, terms like “advantageous”, “exemplary” or “preferred” indicate elements or dimensions which are particularly suitable (but not essential) to the invention or an embodiment thereof, and may be modified wherever deemed suitable by the skilled annotator, except where expressly required.

Without further elaboration, it is believed that one skilled in the art can use the preceding description to use the claimed inventions to their fullest extent. The examples and aspects disclosed herein are to be construed as merely illustrative and not a limitation of the scope of the present disclosure in any way. It will be apparent to those having skill in the art that changes may be made to the details of the above-described examples without departing from the underlying principles discussed. In other words, various modifications and improvements of the examples specifically disclosed in the description above are within the scope of the appended claims. For instance, any suitable combination of features of the various examples described is contemplated.

Within the claims, reference to an element in the singular is not intended to mean “one and only one” unless specifically stated as such, but rather as “one or more” or “at least one”. Unless specifically stated otherwise, the term “some” refers to one or more. No claim element is to be construed under the provision of 35 U.S.C. § 112(f) unless the element is expressly recited using the phrase “means for” or “step for”. All structural and functional equivalents to the elements of the various embodiments described in the present disclosure that are known or come later to be known to those of ordinary skill in the relevant art are expressly incorporated herein by reference and are intended to be encompassed by the claims. Moreover, nothing disclosed in the present disclosure is intended to be dedicated to the public regardless of whether such disclosure is explicitly recited in the claims.

What is claimed is:

1. A device, comprising:
a data rate signal input:
a digital signal input:
a weight generator connected to the digital signal input to generate a weight signal via a weight signal output:
an adder having a digital signal output, a first addition input connected to the weight signal output, and a second addition input connected to the digital signal output: and
an AND-gate having a first input connected to the input data rate signal input and a second input connected to the digital signal input to produce a logical output that gates output from the digital signal output of the adder.

2. The device of claim 1, wherein the weight generator includes:
a subtractor having a difference output, a minuend input connected to the difference output, and a subtrahend input:
a ripple counter, connected to the subtrahend input:
a first register, connected to the input data rate signal input and between the difference output and the weight signal output to time gate the subtractor: and
a second register, connected to the ripple counter and the input data rate signal input to time gate the ripple counter.

3. The device of claim 1, wherein the weight generator includes:
a subtractor/adder having a difference/sum output, a first input connected to the difference/sum output, a second input, and a subtraction/addition selector input:
a counter, connected to the second input, the data rate signal input, and a second data rate signal input:
a first register, connected to the data rate signal input and between the difference output and the weight signal output to time gate the subtractor/adder; and
a second register, connected to the counter and the second input data rate signal input to time gate output from the counter to the subtractor/adder; and
a cycle signal input connected to an up/down count selector input of the counter and the subtraction/addition selector input to alter whether the counter counts upward or downward and whether the second input is added to the first input or subtracted from the first input of the subtractor/adder based on a predetermined number of clock cycles.

4. The device of claim 1, wherein the weight generator includes:
a second subtractor having a second difference output, a second first input connected to the second difference output, a selector input, and a second subtraction selector input:
a counter, connected to the selector input, the data rate signal input, and a second data rate signal input:
a first register, connected to the data rate signal input and between the difference/sum output and the weight signal output to time gate the second subtractor: and
a second register, connected to the counter and the second input data rate signal input to time gate output from the counter to the second subtractor; and
a cycle signal input connected to a down count selector input of the counter and the second subtraction selector input to alter whether the counter counts upward or downward and that the second input is subtracted from the first input of the subtractor based on a predetermined number of clock cycles.

5. The device of claim 1, wherein the weight generator includes:
a second adder having a second sum output, a second first input connected to the sum output, a selector input, and an addition selector input:
a counter, connected to the selector input, the data rate signal input, and a second data rate signal input:
a first register, connected to the data rate signal input and between the sum output and the weight signal output to time gate the second adder; and
a second register, connected to the counter and the second input data rate signal input to time gate output from the counter to the second adder; and
a cycle signal input connected to an up/down count selector input of the counter and the addition selector input to alter whether the counter counts upward or downward and that the second input is added to the first input of the second adder based on a predetermined number of clock cycles.

6. The device of claim 1, operating according to a filter kernel of:
$$\\ {w}_{n} = {\sum }_{i = 1}^{N} i - {\sum }_{i = 1}^{n - 1} i = \frac{{{N}^{}}^{2} + N}{2} - \frac{{{n}^{}}^{2} - n}{2} ,$$
where N and n are filter coefficients.

7. The device of claim 1, operating according to a filter kernel of:
$$\\ {w}_{n} = \{ \begin{matrix}\frac{{{N}^{}}^{2} + N}{2} - \frac{{( N - n + 1 )}^{2} - ( N - n + 1 )}{2} \\ n = 1 , 2 , … , N ; \\ \frac{{{N}^{}}^{2} + N}{2} - \frac{{( n - N + 1 )}^{2} - ( n - N + 1 )}{2} \\ n = N + 1 , … , 2 N - 1 ;\end{matrix} ,$$
where N and n are filter coefficients.

8. A linear decimation filter, comprising:
a weight generator, configured to generate a weight signal based on a digital input signal;
an adder, configured to generate a digital output signal based on the weight signal and the digital signal output from an earlier clock cycle; and
an AND-gate, configured to gate output from the adder based on the digital input signal and an input data rate signal.

9. The filter of claim 8, wherein the weight generator includes:
a subtractor having a difference output, a minuend input connected to the difference output, and a subtrahend input;
a ripple counter, connected to the subtrahend input;
a first register, configured to time gate the subtractor; and
a second register, configured to time gate the ripple counter based on the input data rate signal.

10. The filter of claim 8, wherein the weight generator includes:
a subtractor/adder, configured to produce a selected one of a difference output or a sum output based on an add/subtract selection signal, a first input to the subtractor/adder, and a second input to the subtractor/adder;
a counter, configured to provide the second input to the subtractor/adder based on an count stored in the counter that is affected by an up/down count selector input to count upwards or downwards for a given clock cycle, wherein the up/down count selector input selects which one of the difference output or the sum output that the subtractor/adder produces for the given clock cycle.

11. The filter of claim 10, wherein the subtractor/adder operates to produce the sum output when the counter operations to count upwards.

12. The filter of claim 10, wherein the subtractor/adder operates to produce the difference output when the counter operations to count downwards.

13. The filter of claim 8, operating according to a filter kernel of:
$$\\ {w}_{n} = {\sum }_{i = 1}^{N} i - {\sum }_{i = 1}^{n - 1} i = \frac{{{N}^{}}^{2} + N}{2} - \frac{{{n}^{}}^{2} - n}{2} ,$$
where N and n are filter coefficients.

14. The filter of claim 8, operating according to a filter kernel of:
$$\\ {w}_{n} = \{ \begin{matrix}\frac{{{N}^{}}^{2} + N}{2} - \frac{{( N - n + 1 )}^{2} - ( N - n + 1 )}{2} \\ n = 1 , 2 , … , N ; \\ \frac{{{N}^{}}^{2} + N}{2} - \frac{{( n - N + 1 )}^{2} - ( n - N + 1 )}{2} \\ n = N + 1 , … , 2 N - 1 ;\end{matrix} ,$$
where N and n are filter coefficients.
